(19) United States
(12) Patent Application Publication
(10) Pub. No.: US 2023/0160103 A1
(43) Pub. Date: May 25, 2023

(54) SILICON CARBIDE SINGLE CRYSTAL AND METHOD OF MANUFACTURING SILICON CARBIDE SINGLE CRYSTAL

(71) Applicant: SUMITOMO ELECTRIC INDUSTRIES, LTD., Osaka (JP)

(72) Inventor: Shogo SAKAIYA, Osaka (JP)

(21) Appl. No.: 17/919,222

(22) PCT Filed: Mar. 3, 2021
(86) PCT No.: PCT/JP2021/008195

§ 371 Date: Oct. 14, 2022

(30) Foreign Application Priority Data
Apr. 22, 2020 (JP) 2020-075940

(51) Int. Cl. C30B 29/36; C30B 23/06

(52) U.S. Cl. CPC C30B 29/36; C30B 23/063

(57) ABSTRACT

A silicon carbide single crystal has a first main surface, a second main surface, a first silicon carbide region, and a second silicon carbide region. The first silicon carbide region and the second silicon carbide region each include a silicon carbide single crystal of 4H polytype. A value obtained by dividing the number of void defects in the first silicon carbide region by the sum of the number of the void defects in the first silicon carbide region and the number of void defects in the second silicon carbide region is 0.8 or more. In a cross section parallel to the first main surface, the void defect each have a major axis of 1 μm to 1000 μm.

### TECHNICAL FIELD

The present disclosure relates to silicon carbide single crystals and methods of manufacturing silicon carbide single crystals. This application claims priority based on Japanese Patent Application No. 2020-075940 filed on Apr. 22, 2020. The entire contents of the Japanese patent application are incorporated herein by reference.

### BACKGROUND ART

Japanese Unexamined Patent Application Publication No. 1997-157091 (PTL 1) describes a method of growing single-crystal silicon carbide by a sublimation recrystallization method.

### CITATION LIST

### Patent Literature

PTL 1: Japanese Unexamined Patent Application Publication No. 1997-157091

### SUMMARY OF INVENTION

A silicon carbide single crystal according to the present disclosure includes a first main surface, a second main surface, a first silicon carbide region and a second silicon carbide region. The second main surface is located opposite to the first main surface and protrudes outward. The first silicon carbide region constitutes the first main surface and is located between the first main surface and an imaginary plane separated by 10 mm from the first main surface. The second silicon carbide region constitutes the second main surface and is contiguous to the first silicon carbide region. The first silicon carbide region and the second silicon carbide region each include a silicon carbide single crystal of 4H polytype. A value obtained by dividing the number of void defects in the first silicon carbide region by a sum of the number of the void defects in the first silicon carbide region and the number of void defects in the second silicon carbide region is 0.8 or more. In a cross section parallel to the first main surface, the void defects each have a major axis of 1 μm to 1000 μm.

A method of manufacturing a silicon carbide single crystal according to the present disclosure includes: disposing a silicon carbide seed substrate and a silicon carbide source material in a crucible, the silicon carbide seed substrate having a growth surface facing the silicon carbide source material and an attachment surface opposite to the growth surface, forming a first silicon carbide region on the growth surface by sublimating the silicon carbide source material while maintaining a temperature of the growth surface at 2100° C. or higher and lower than 2200° C., and forming a second silicon carbide region on the first silicon carbide region by sublimating the silicon carbide source material while maintaining the temperature of the growth surface at 2200° C. or higher, a pressure in the crucible at 0.5 kPa or less, and a temperature gradient between the growth surface and a surface of the silicon carbide source material at 0.4° C./mm or less. The first silicon carbide region and the second silicon carbide region each include a silicon carbide single crystal of 4H polytype.

### BRIEF DESCRIPTION OF DRAWINGS

FIG. 1 is a schematic side view showing the structure of a silicon carbide single crystal according to an embodiment of the present disclosure.

FIG. 2 is a schematic cross-sectional view taken along line II-II of FIG. 1.

FIG. 3 is a partial cross-sectional schematic view showing the structure of a silicon carbide single crystal manufacturing device according to the embodiment of the present disclosure.

FIG. 4 is a flow chart schematically showing a method of manufacturing a silicon carbide single crystal according to the embodiment of the present disclosure.

FIG. 5 is a partial cross-sectional schematic view showing a step of disposing a silicon carbide seed substrate and a silicon carbide source material in a crucible.

FIG. 6 is a partial cross-sectional schematic view showing a step of forming a first silicon carbide region.

FIG. 7 is a partial cross-sectional schematic view showing a step of forming a second silicon carbide region.

FIG. 8 is a graph showing the relationship between the growth surface temperature of a silicon carbide seed substrate and the mixing rate of different polytypes mixed in a silicon carbide single crystal formed on the silicon carbide seed substrate.

FIG. 9 is a graph showing the relationship between the temperature gradient between the growth surface of the silicon carbide seed substrate and the surface of the silicon carbide source material and the aggregation rate of void defects.

### DETAILED DESCRIPTION

### Problems to be Solved by the Present Disclosure

An object of the present disclosure is to provide a silicon carbide single crystal and a method of manufacturing the silicon carbide single crystal capable of reducing the number of void defects while suppressing generation of different polytypes.

### Advantageous Effects of the Present Disclosure

According to the present disclosure, it is possible to provide a silicon carbide single crystal and a method of manufacturing the silicon carbide single crystal capable of reducing the number of void defects while suppressing generation of different polytypes.

### Summary of Embodiments of the Present Disclosure

First, an outline of embodiments of the present disclosure will be described.

(1) A silicon carbide single crystal 10 according to the present disclosure includes a first main surface 1, a second main surface 2, a first silicon carbide region 11 and a second silicon carbide region 12. Second main surface 2 is located opposite to first main surface 1 and protrudes outward. First silicon carbide region 11 constitutes first main surface 1 and is located between first main surface 1 and an imaginary plane separated by 10 mm from first main surface 1. Second silicon carbide region 12 constitutes second main surface 2 and is contiguous to first silicon carbide region 11. First silicon carbide region 11 and second silicon carbide region 12 each include a silicon carbide single crystal of 4H polytype. A value obtained by dividing the number of void defects 6 in first silicon carbide region 11 by a sum of the number of void defects 6 in first silicon carbide region 11 and the number of void defects 6 in second silicon carbide region 12 is 0.8 or more. In a cross section parallel to first main surface 1, void defects 6 each have a major axis of 1 μm to 1000 μm.

(2) In silicon carbide single crystal 10 according to (1), in a direction perpendicular to first main surface 1, silicon carbide single crystal 10 may have a thickness of 30 mm or more.

(3) In silicon carbide single crystal 10 according to (1) or (2), in a cross section parallel to first main surface 1, an area density of void defects 6 in first silicon carbide region 11 may be 0.1/cm² or more.

(4) A method of manufacturing silicon carbide single crystal 10 according to the present disclosure includes: disposing silicon carbide seed substrate 20 and silicon carbide source material 23 in crucible 30, silicon carbide seed substrate 20 having growth surface 21 facing silicon carbide source material 23 and attachment surface 22 opposite to growth surface 21; forming first silicon carbide region 11 on growth surface 21 by sublimating silicon carbide source material 23 while maintaining a temperature of growth surface 21 at 2100° C. or higher and lower than 2200° C.; and forming second silicon carbide region 12 on first silicon carbide region 11 by sublimating silicon carbide source material 23 while maintaining the temperature of growth surface 21 at 2200° C. or higher, a pressure in crucible 30 at 0.5 kPa or less, and a temperature gradient between growth surface 21 and a surface of silicon carbide source material 23 at 0.4° C./mm or less. First silicon carbide region 11 and second silicon carbide region 12 each include a silicon carbide single crystal of 4H polytype.

(5) In the method of manufacturing silicon carbide single crystal 10 according to (4), first silicon carbide region 11 may have a thickness of 10 mm or less.

(6) In the method of manufacturing silicon carbide single crystal 10 according to (4) or (5), silicon carbide single crystal 10 may have a thickness of 30 mm or more.

### Details of Embodiments of Present Disclosure

Embodiments of the present disclosure (hereinafter also referred to as embodiments of the present disclosure) will be described in detail below with reference to the drawings. In the following drawings, the same or corresponding portions are denoted by the same reference numerals, and description thereof will not be repeated.

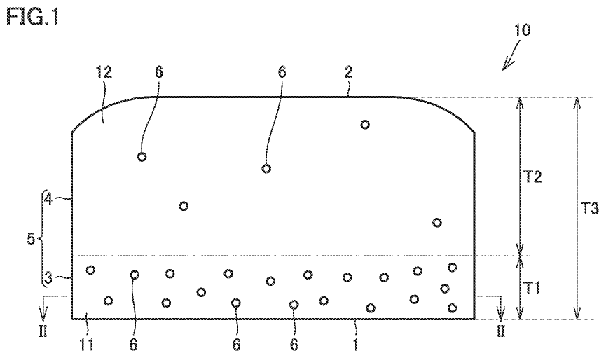

First, the configuration of a silicon carbide single crystal 10 according to the embodiment of the present disclosure will be described. FIG. 1 is a schematic side view showing the structure of a silicon carbide single crystal according to the embodiment of the present disclosure. As shown in FIG. 1, silicon carbide single crystal 10 according to the embodiment of the present disclosure mainly includes a first main surface 1, a second main surface 2, an outer peripheral surface 5, a first silicon carbide region 11, and a second silicon carbide region 12. Second main surface 2 is located opposite to first main surface 1. Second main surface 2 protrudes outward. First main surface 1 is, for example, a flat surface. Outer peripheral surface 5 is contiguous to each of first main surface 1 and second main surface 2. Silicon carbide single crystal 10 according to the embodiment of the present disclosure has a substantially cylindrical shape.

As shown in FIG. 1, first silicon carbide region 11 constitutes first main surface 1. First silicon carbide region 11 is a region within 10 mm from first main surface 1. First silicon carbide region 11 is located between first main surface 1 and an imaginary plane separated by 10 mm from first main surface 1. In a direction perpendicular to first main surface 1, a thickness of first silicon carbide region 11 (first thickness T1) is 10 mm. Second silicon carbide region 12 constitutes second main surface 2. Second silicon carbide region 12 is contiguous to first silicon carbide region 11. Second silicon carbide region 12 is provided on first silicon carbide region 11. Outer peripheral surface 5 has a first outer peripheral surface portion 3 and a second outer peripheral surface portion 4. Second outer peripheral surface portion 4 is contiguous to first outer peripheral surface portion 3.

First silicon carbide region 11 and second silicon carbide region 12 each include a silicon carbide single crystal of 4H polytype. First silicon carbide region 11 constitutes first outer peripheral surface portion 3. Second silicon carbide region 12 constitutes second outer peripheral surface portion 4. In a direction perpendicular to first main surface 1, a thickness of second silicon carbide region 12 (second thickness T2) is 20 mm or more, for example. In a direction perpendicular to first main surface 1, a thickness of silicon carbide single crystal 10 (third thickness T3) is 30 mm or more, for example. The lower limit of third thickness T3 is not particularly limited, may have a thickness of 35 mm or more, or 40 mm or more, for example.

As shown in FIG. 1, void defects 6 are present in each of first silicon carbide region 11 and second silicon carbide region 12. A void defect 6 is a hollow defect confined and formed in the silicon carbide region. In other words, void defect 6 is not exposed on the outer surface of the silicon carbide region. Void defects 6 are substantially spherical. In a cross section parallel to first main surface 1, the shape of void defect 6 is, for example, elliptical. In the cross section parallel to first main surface 1, a major axis of the shape of each of void defects 6 is 1 μm to 1000 μm, for example.

A value obtained by dividing the number of void defects 6 in first silicon carbide region 11 by a sum of the number of void defects 6 in first silicon carbide region 11 and the number of void defects 6 in second silicon carbide region 12 is 0.8 or more. In other words, 80% or more of the total number of void defects 6 present in silicon carbide single crystal 10 are present in first silicon carbide region 11. The number of void defects 6 present in second silicon carbide region 12 is less than 20% of the total number of void defects 6 present in silicon carbide single crystal 10.

The lower limit of the value obtained by dividing the number of void defects 6 in first silicon carbide region 11 by a sum of the number of void defects 6 in first silicon carbide region 11 and the number of void defects 6 in second silicon carbide region 12 is not particularly limited, and may be, for example, 0.85 or more, 0.90 or more, or 0.95 or more.

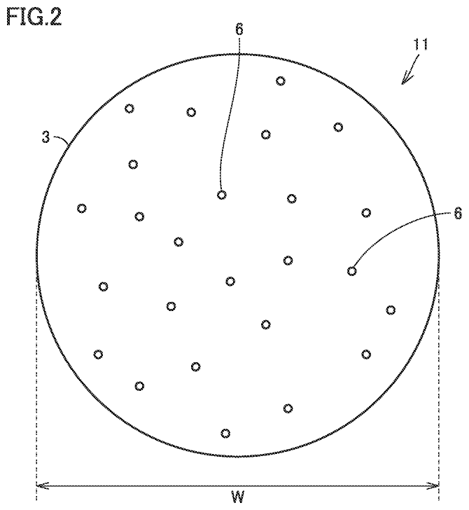

FIG. 2 is a schematic cross-sectional view taken along line II-II of FIG. 1. As shown in FIG. 2, first silicon carbide region 11 is substantially circular when viewed in a direction perpendicular to first main surface 1. Similarly, when viewed in a direction perpendicular to first main surface 1, second silicon carbide region 12 is substantially circular. A diameter W of first silicon carbide region 11 is, for example, 150 mm. The lower limit of diameter W is not particularly limited, but may be, for example, 100 mm or more. The upper limit of diameter W is not particularly limited, and may be, for example, 200 mm or less, or 300 mm or less.

As shown in FIG. 2, in the cross section parallel to first main surface 1, the area density of void defects 6 in first silicon carbide region 11 may be 0.1/cm² or more. The lower limit of the area density of void defects 6 in first silicon carbide region 11 is not particularly limited, and may be, for example, 0.5/cm² or more, or 1/cm² or more. The upper limit of the area density of void defects 6 in first silicon carbide region 11 is not particularly limited, and may be, for example, 10/cm² or less, or 5/cm² or less. In the cross section parallel to first main surface 1, the area density of void defects 6 in first silicon carbide region 11 may be greater than the area density of void defects 6 in second silicon carbide region 12.

Next, a method of measuring void defect 6 will be described. Void defect 6 can be observed using, for example, a transmission type optical microscope. For example, a silicon carbide single crystal substrate cut out from silicon carbide single crystal 10 using a multi-wire saw is observed with the transmission type optical microscope, void defects 6 present in the silicon carbide single crystal substrate are specified, and the number thereof is measured. By measuring the number of void defects 6 for all silicon carbide single crystal substrates using this method, the number of void defects 6 present in first silicon carbide region 11 and second silicon carbide region 12 can be obtained.

The area density of void defects 6 in first silicon carbide region 11 is a value obtained by dividing the number of void defects 6 present in first silicon carbide region 11 by the cross-sectional area of first silicon carbide region 11 in the cross section parallel to first main surface 1. Similarly, the area density of void defects 6 in second silicon carbide region 12 is a value obtained by dividing the number of void defects 6 present in second silicon carbide region 12 by the cross-sectional area of second silicon carbide region 12 in a cross section parallel to first main surface 1.

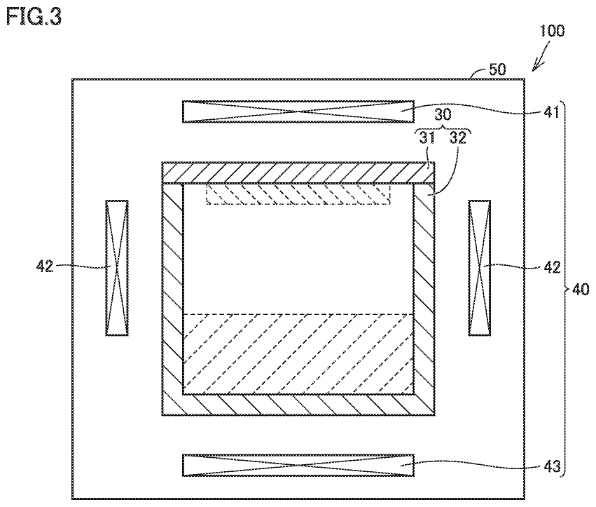

Next, a configuration of a manufacturing device for silicon carbide single crystal 10 according to the embodiment of the present disclosure will be described. FIG. 3 is a partial cross-sectional schematic view showing the structure of a silicon carbide single crystal manufacturing device according to the embodiment of the present disclosure. As shown in FIG. 3, a manufacturing device 100 for the silicon carbide single crystal mainly includes a chamber 50, a crucible 30, and a heater 40. Crucible 30 and heater 40 are disposed inside chamber 50. Crucible 30 has a source material container portion 32 and a lid portion 31. Lid portion 31 is disposed on source material container portion 32. Heater 40 is, for example, a resistive heater. A voltage is applied to heater 40 from an external power supply (not shown). Thus, heater 40 itself generates heat to heat crucible 30.

Heater 40 includes, for example, a first resistive heater 41, a second resistive heater 42, and a third resistive heater 43. First resistive heater 41 is disposed above lid portion 31. Second resistive heater 42 is disposed to surround outer peripheral surface 5 of source material container portion 32. Third resistive heater 43 is disposed below source material container portion 32. A radiation thermometer (not shown) may be disposed outside chamber 50.

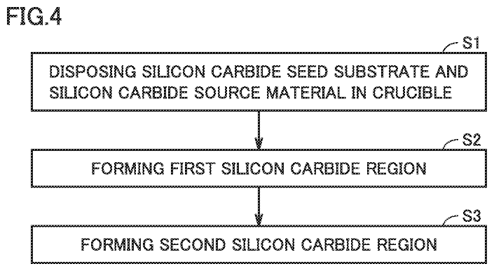

Next, a method of manufacturing silicon carbide single crystal 10 according to the embodiment of the present disclosure will be described. FIG. 4 is a flow chart schematically showing a method of manufacturing a silicon carbide single crystal according to the embodiment of the present disclosure. As shown in FIG. 4, the method of manufacturing silicon carbide single crystal 10 according to the embodiment of the present disclosure mainly includes disposing a silicon carbide seed substrate and a silicon carbide source material in a crucible (S1), forming the first silicon carbide region (S2), and forming the second silicon carbide region (S3).

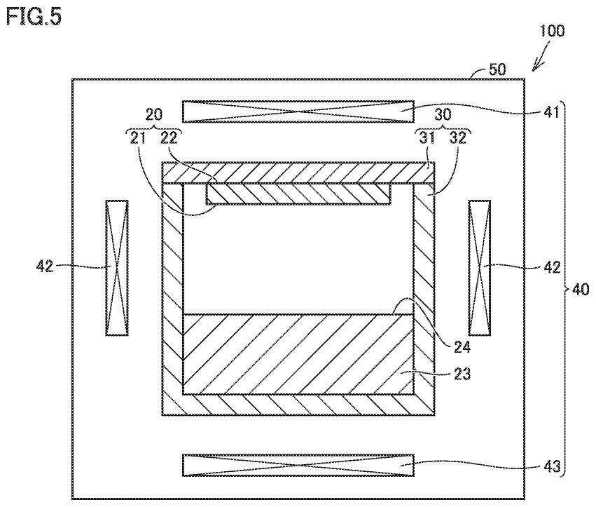

First, disposing a silicon carbide seed substrate and a silicon carbide source material in a crucible (S1) is performed. FIG. 5 is a partial cross-sectional schematic view showing a step of disposing a silicon carbide seed substrate 20 and a silicon carbide source material 23 in crucible 30.

As shown in FIG. 5, silicon carbide source material 23 is disposed within source material container portion 32. Silicon carbide source material 23 is, for example, polycrystalline silicon carbide powder. Silicon carbide seed substrate 20 is secured to lid portion 31 using, for example, an adhesive (not shown). Silicon carbide seed substrate 20 has a growth surface 21 and an attachment surface 22. Attachment surface 22 located opposite to growth surface 21. Growth surface 21 faces silicon carbide source material 23. Attachment surface 22 faces lid portion 31. Silicon carbide seed substrate 20 is disposed such that growth surface 21 faces the surface of silicon carbide source material 23.

Silicon carbide seed substrate 20 is, for example, a hexagonal silicon carbide single crystal of polytype 4H. The diameter of growth surface 21 is, for example, 150 mm. The diameter of growth surface 21 may be 150 mm or more. Growth surface 21 is, for example, the {0001} plane or a plane inclined by an off angle of about 8° or less with respect to the {0001} plane. As described above, silicon carbide seed substrate 20 and silicon carbide source material 23 are disposed in crucible 30.

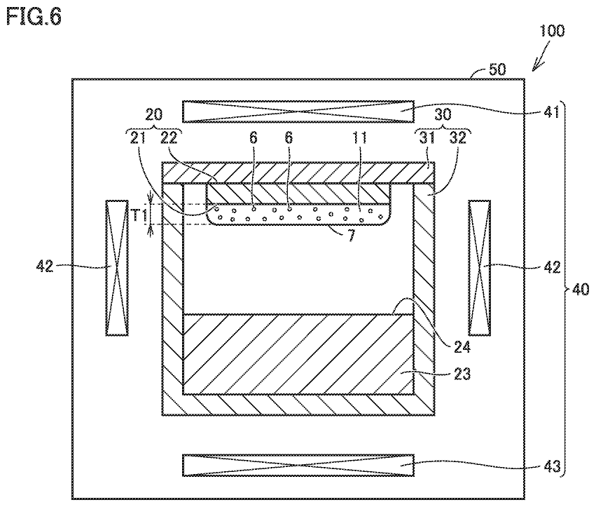

Next, forming a first silicon carbide region (S2) is performed. FIG. 6 is a partial cross-sectional schematic view showing a step of forming a first silicon carbide region.

First, growth surface 21 is heated to a temperature of, for example, 2100° C. or higher and lower than 2200° C. The lower limit of the temperature of growth surface 21 is not particularly limited, and may be, for example, 2110° C. or higher, or 2120° C. or higher. The upper limit of the temperature of growth surface 21 is not particularly limited, and may be, for example, 2190° C. or less, or 2180° C. or less. While the temperature of growth surface 21 is rising, an atmospheric gas pressure in crucible 30 is maintained at, for example, about 80 kPa. The atmospheric gas contains an inert gas such as argon gas, helium gas or nitrogen gas. The temperature of growth surface 21 can be calculated, for example, by finite element analysis of the temperature distribution in the furnace based on the temperature of the crucible outer wall measured by a radiation thermometer.

A temperature gradient is provided between growth surface 21 of silicon carbide seed substrate 20 and the surface of silicon carbide source material 23 so that the temperature of growth surface 21 of silicon carbide seed substrate 20 is lower than the temperature of the surface of silicon carbide source material 23. The voltage applied to each of first resistive heater 41, second resistive heater 42, and third resistive heater 43 is controlled such that the temperature gradient between growth surface 21 of silicon carbide seed substrate 20 and the surface of silicon carbide source material 23 is greater than 0.4° C./mm, for example.

The atmospheric gas pressure in crucible 30 is then reduced to, for example, 1.0 kPa. As a result, silicon carbide source material 23 in the accommodation portion starts to sublimate, and the sublimated silicon carbide gas recrystallizes on growth surface 21 of silicon carbide seed substrate 20. First silicon carbide region 11 begins to grow on growth surface 21 of the silicon carbide seed crystal. During the growth of first silicon carbide region 11, a pressure in crucible 30 is maintained at about 0.1 kPa to 3 kPa, for example. The pressure in crucible 30 is measured using, for example, a pressure gauge (not shown) attached to chamber 50.

As described above, first silicon carbide region 11 is formed on growth surface 21 by sublimating silicon carbide source material 23 while maintaining the temperature of growth surface 21 at 2100° C. or higher and lower than 2200° C. (see FIG. 6). First silicon carbide region 11 includes a silicon carbide single crystal of 4H polytype. The thickness of first silicon carbide region 11 (first thickness T1) is, for example, 10 mm or less. The upper limit of the thickness of first silicon carbide region 11 is not particularly limited and may be, for example, 8 mm or less or 6 mm or less.

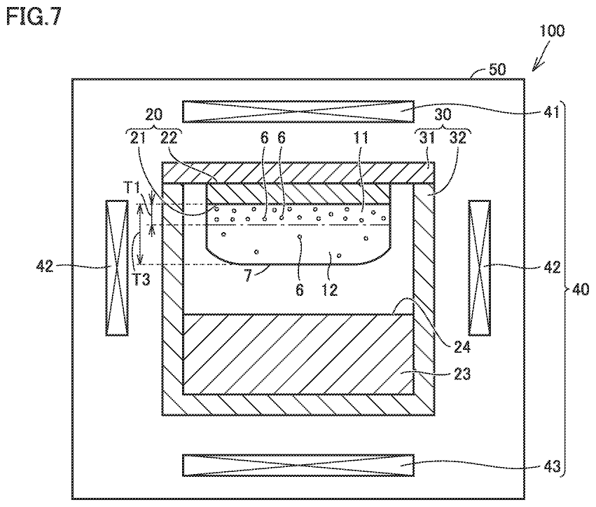

Next, forming a second silicon carbide region (S3) is performed. FIG. 7 is a partial cross-sectional schematic view showing a step of forming a second silicon carbide region.

A temperature of growth surface 21 in forming the second silicon carbide region (S3) is set to be higher than the temperature of growth surface 21 in forming the first silicon carbide region (S2). In particular, the temperature of growth surface 21 in forming the second silicon carbide region (S3) is 2200° C. or higher. The lower limit of the temperature of growth surface 21 in forming the second silicon carbide region (S3) is not particularly limited, and may be, for example, 2210° C. or higher, or 2220° C. or higher.

The pressure in crucible 30 in forming the second silicon carbide region (S3) is, for example, 0.5 kPa or less. The upper limit of the pressure in crucible 30 in forming the second silicon carbide region (S3) is not particularly limited, and may be, for example, 0.4 kPa or less, or 0.3 kPa or less.

A temperature gradient between growth surface 21 and a surface 24 of silicon carbide source material 23 in forming the second silicon carbide region (S3) may be 0.4° C./mm or less. The upper limit of the temperature gradient between growth surface 21 and surface 24 of silicon carbide source material 23 is not particularly limited, but may be, for example, 0.35° C./mm or less, or 0.3° C./mm or less.

Accordingly, silicon carbide source material 23 in the accommodation portion is sublimated, and the sublimated silicon carbide gas recrystallizes on first silicon carbide region 11. As described above, second silicon carbide region 12 is formed on first silicon carbide region 11 by sublimating silicon carbide source material 23 while maintaining the temperature of growth surface 21 at 2200° C. or higher, a pressure in crucible 30 at 0.5 kPa or less, and the temperature gradient between growth surface 21 and the surface of silicon carbide source material 23 at 0.4° C./mm or less.

Second silicon carbide region 12 includes a silicon carbide single crystal of 4H polytype. The thickness of silicon carbide single crystal 10 (third thickness T3) is, for example 30 mm or more. The lower limit of the thicknesses of silicon carbide single crystal 10 is not particularly limited, and may be, for example, 35 mm or more, or 40 mm or more.

In the method of manufacturing a silicon carbide single crystal according to the above embodiment, heater 40 is a resistive heater, but heater 40 is not limited to a resistive heater. The heater may be, for example, an induction heating coil.

Next, effects of the silicon carbide single crystal and the method of manufacturing a silicon carbide single crystal according to the embodiment of the present disclosure will be described.

At a high temperature, a silicon carbide single crystal of 4H polytype is more stably present than a silicon carbide single crystal of 6H polytype. Therefore, in the case of producing a silicon carbide single crystal of 4H polytype, it is desirable to lower the temperature of the growing surface in order to prevent the silicon carbide single crystal of 6H polytype from being mixed.

On the other hand, when the temperature of the growing surface is lowered, a thermodynamically stable {11-20} plane, {1-100} plane or the like is easily generated. Therefore, for example, when a growing surface 7 is a {0001} plane, void defect 6 is likely to occur due to an increase in the height of a plane perpendicular to growing surface 7 or the like. Alternatively, when the temperature of the growth surface is lowered, the temperature environment or the gas composition in the vicinity of the growth surface deviates from appropriate conditions, so that silicon droplets are generated, and silicon diffuses into the crystal during growth, thereby forming void defect 6. When the temperature gradient in the longitudinal direction (growth direction) increases, sublimation and recrystallization proceed inside void defect 6. As a result, void defects 6 move near growing surface 7 and are distributed in a wide region of the silicon carbide single crystal. In the region through which void defect 6 has passed, the crystallinity deteriorates as compared with the region through which void defect 6 has not passed.

According to the method of manufacturing silicon carbide single crystal 10 in accordance with the embodiment of the present disclosure, first silicon carbide region 11 is formed on growth surface 21 by sublimating silicon carbide source material 23 while maintaining the temperature of growth surface 21 of silicon carbide seed substrate 20 at 2100° C. or higher and lower than 2200° C. Thus, it is possible to form first silicon carbide region 11 having a surface protruding outward while suppressing the mixing of silicon carbide single crystal of 6H polytype. In first silicon carbide region 11, although void defect 6 is generated, the growth of the silicon carbide single crystal of 4H polytype is stabilized. As a result, it is possible to suppress mixing of a different polytype such as 6H in silicon carbide single crystal 10.

Next, second silicon carbide region 12 is formed on first silicon carbide region 11 by sublimating silicon carbide source material 23 while maintaining the temperature of growth surface 21 to 2200° C. or higher, the pressure in crucible 30 to 0.5 kPa or less, and the temperature gradient between growth surface 21 and surface 24 of silicon carbide source material 23 at 0.4° C./mm or less. By increasing the temperature of growth surface 21, new generation of void defect 6 can be suppressed. When the temperature of growth surface 21 is increased, the temperature gradient between growth surface 21 and surface 24 of silicon carbide source material 23 is decreased, thereby decreasing the growth rate. Therefore, by lowering the pressure in crucible 30, silicon carbide source material 23 is easily sublimated, so that a decrease in the growth rate of the silicon carbide single crystal can be prevented.

Further, by lowering the temperature gradient between growth surface 21 and surface 24 of silicon carbide source material 23, the temperature gradient inside void defect 6 is also lowered. Therefore, sublimation and recrystallization can be suppressed from occurring inside void defect 6. As a result, it can be suppressed that void defect 6 move near growing surface 7 (see FIG. 7). Therefore, it is possible to suppress the generation of void defect 6 in second silicon carbide region 12 grown in the later stage of growth.

According to silicon carbide single crystal 10 of the embodiment of the present disclosure, first silicon carbide region 11 constitutes first main surface 1 and is within a 10 mm from first main surface 1. Second silicon carbide region 12 constitutes second main surface 2 and is contiguous to first silicon carbide region 11. A value obtained by dividing the number of void defects 6 in first silicon carbide region 11 by a sum of the number of void defects 6 in first silicon carbide region 11 and the number of void defects 6 in second silicon carbide region 12 is 0.8 or more. This makes it possible to secure a large number of silicon carbide single crystal substrates on which devices can be fabricated.

### Example 1

(Experimental Method)

Silicon carbide single crystal 10 was formed on silicon carbide seed substrate 20. The temperatures of growth surface 21 of silicon carbide seed substrate 20 were 2125° C., 2150° C., 2175° C., 2200° C., 2225° C., and 2250° C., respectively. The pressure in crucible 30 was greater than 0.5 kPa. The temperature gradient between growth surface 21 of silicon carbide seed substrate 20 and surface 24 of silicon carbide source material 23 was greater than 0.4° C./mm. The voltage applied to each of first resistive heater 41, second resistive heater 42, and third resistive heater 43 was controlled so as to satisfy the above-described growth conditions. The target polytype of silicon carbide single crystal 10 is 4H. The main heterologous polytype is 6H.

The mixing rate of different polytypes in silicon carbide single crystal 10 formed on growth surface 21 of silicon carbide seed substrate 20 was obtained. The mixing rate of different polytypes is the probability that a polytype other than 4H is mixed into the grown silicon carbide single crystal. That is, it is a ratio obtained by dividing the number of mixed polytypes other than 4H among the grown silicon carbide single crystals by the total number of grown silicon carbide single crystals. The method for measuring the mixing rate of different polytypes is as follows. Examples of the method for measuring the polytype include a method in which a silicon carbide single crystal is processed into a wafer shape, a transmission optical microscope image is taken, and the polytype is determined based on a difference in color, and a method in which the polytype is determined based on the contrast of a photoluminescence (PL) imaging image. At this time, the measurement was performed by the later method. PLIS-100 manufactured by Photon Design Co., Ltd. was used as a measuring apparatus. The exciting light was a He—Cd laser of 325 nm. The exposure time was 1 second. A 750 nm low pass filter was inserted on the light receiving side. The presence or absence of different polytypes was detected by the contrast difference of the measured images.

(Experimental Results)

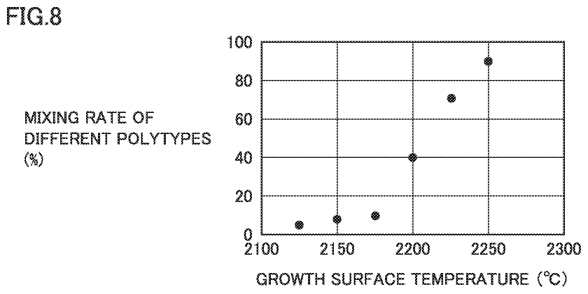

FIG. 8 is a graph showing the relationship between the growth surface temperature of silicon carbide seed substrate 20 and the mixing rate of different polytypes mixed in first silicon carbide region 11 of silicon carbide single crystal 10 formed on silicon carbide seed substrate 20. Table 1 shows the data of FIG. 8. As shown in FIG. 8 and Table 1, as the temperature of growth surface 21 decreases, the mixing rate of the different polytypes decreases. By setting the temperature of growth surface 21 to less than 2200° C., the mixing rate of different polytypes can be significantly reduced.

TABLE 1

| | Mixing |
|---|---|
| Growth | Rate of |
| Surface | Different |
| Temperature | Polytypes |
| (° C.) | (%) |
| 2125 | 5 |
| 2150 | 8 |
| 2175 | 10 |
| 2200 | 40 |
| 2225 | 70 |
| 2250 | 90 |

### Example 2

(Experimental Method)

Silicon carbide single crystal 10 was formed on silicon carbide seed substrate 20 using the growth conditions of Samples 2-1 to 2-6. The temperature gradients between growth surface 21 of silicon carbide seed substrate 20 and surface 24 of silicon carbide source material 23 under the growth conditions of the samples 2-1 to 2-6 were 0.2° C./mm, 0.4° C./mm, 0.6° C./mm, 0.8° C./mm, 1° C./mm, and 1.2° C./mm, respectively. The pressure in crucible 30 was 0.5 kPa. Growth surface 21 of silicon carbide seed substrate 20 was set at 2150° C. The voltage applied to each of first resistive heater 41, second resistive heater 42, and third resistive heater 43 was controlled so as to satisfy the above-described growth conditions.

(Experimental Results)

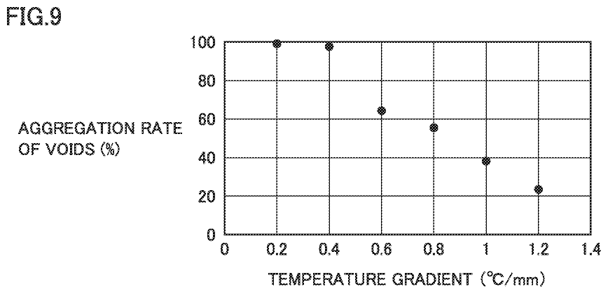

FIG. 9 is a graph showing the relationship between the temperature gradient between growth surface 21 of silicon carbide seed substrate 20 and surface 24 of silicon carbide source material 23 and the aggregation rate of void defects 6. Table 2 shows the data of FIG. 9. It is a value obtained by dividing the number of void defects 6 in first silicon carbide region 11 within the 10 mm from growth surface 21 by a sum of the number of void defects 6 present in entire silicon carbide single crystal 10 (first silicon carbide region 11 and second silicon carbide region 12). As shown in FIG. 9 and Table 2, as the temperature gradient between growth surface 21 of silicon carbide seed substrate 20 and the surface of silicon carbide source material 23 decreases, the aggregation rate of void defects 6 increases. By setting the temperature gradient between growth surface 21 of silicon carbide seed substrate 20 and the surface of silicon carbide source material 23 to 0.4° C./mm or less, the aggregation rate of void defects 6 can be significantly increased.

TABLE 2

| | Temperature | Aggregation |
|---|---|---|
| | Gradient | Rate of Voids |
| Sample No. | (° C./mm) | (%) |
| Sample 2-1 | 0.2 | 99 |
| Sample 2-2 | 0.4 | 98 |
| Sample 2-3 | 0.6 | 64 |
| Sample 2-4 | 0.8 | 55 |
| Sample 2-5 | 1 | 38 |
| Sample 2-6 | 1.2 | 23 |

### Example 3

(Experimental Method)

Silicon carbide single crystal 10 was produced on silicon carbide seed substrate 20 under the growth conditions of Samples 3-1 to 3-4. The method of manufacturing silicon carbide single crystal 10 included forming the first silicon carbide region (S2) and forming the second silicon carbide region (S3). The growth conditions of Samples 3-1 to 3-4 are shown in Table 3. The voltage applied to each of first resistive heater 41, second resistive heater 42, and third resistive heater 43 was controlled so as to satisfy the growth conditions shown in Table 3. The growth conditions of Sample 3-1 are Examples. The growth conditions of Samples 3-2 to 3-4 are comparative examples.

(Experimental Results)

TABLE 3

| | First Step | | | Second Step | | | Aggregation |
|---|---|---|---|---|---|---|---|
| | | Growth Surface | Thickness of | | Growth Surface | Temperature | Rate |
| Sample | Pressure | Temperature | Growth | Pressure | Temperature | Gradient | of Voids |
| No. | (kPa) | (° C.) | (mm) | (kPa) | (° C.) | (° C./mm) | (%) |
| Sample | 0.5 | 2180 | 10 | 0.5 | 2240 | 0.2 | 99 |
| 3-1 | | | | | | | |
| Sample | 0.2 | 2120 | 10 | 2 | 2240 | 1 | 38 |
| 3-2 | | | | | | | |
| Sample | 1 | 2150 | 5 | 2 | 2240 | 0.8 | 55 |
| 3-3 | | | | | | | |
| Sample | 0.5 | 2180 | 10 | 2 | 2240 | 1.2 | 23 |
| 3-4 | | | | | | | |

As shown in Table 3, the aggregation rate of void defects 6 in silicon carbide single crystal 10 formed using the growth conditions of Sample 3-1 was significantly higher than the aggregation rate of void defects 6 in silicon carbide single crystal 10 formed using the growth conditions of Samples 3-2 to 3-4. From the above results, it was confirmed that the aggregation rate of void defects 6 can be significantly increased by sublimating silicon carbide source material 23 while maintaining the temperature of growth surface 21 at 2100° C. or higher and lower than 2200° C. in forming the first silicon carbide region (S2), and by sublimating silicon carbide source material 23 while maintaining the temperature of growth surface 21 at 2200° C. or higher, the pressure in crucible 30 at 0.5 kPa or less, and the temperature gradient between growth surface 21 and surface 24 of silicon carbide source material 23 at 0.4° C./mm or less in forming the second silicon carbide region (S3).

It should be understood that the embodiments and examples disclosed herein are illustrative in all respects and are not restrictive. The scope of the present invention is defined not by the above description but by the claims, and is intended to include meanings equivalent to the claims and all modifications within the scope.

### REFERENCE SIGNS LIST

1 first main surface, 2 second main surface, 3 first outer peripheral surface portion, 4 second outer peripheral surface portion, 5 outer peripheral surface, 6 void defect, 7 growing surface, 10 silicon carbide single crystal, 11 first silicon carbide region, 12 second silicon carbide region, 20 silicon carbide seed substrate, 21 growth surface, 22 attachment surface, 23 silicon carbide source material, 24 surface, 30 crucible, 31 lid portion, 32 source material container portion, 40 heater, 41 first resistive heater, 42 second resistive heater, 43 third resistive heater, 50 chamber, 100 manufacturing device, T1 first thickness, T2 second thickness, T3 third thickness, W diameter

1. A silicon carbide single crystal comprising:
a first main surface;
a second main surface located opposite to the first main surface, the second main surface protruding outward; a first silicon carbide region constituting the first main surface, and
a second silicon carbide region constituting the second main surface, the second silicon carbide region being contiguous to the first silicon carbide region,
wherein the first silicon carbide region and the second silicon carbide region each include a silicon carbide single crystal of 4H polytype,
a boundary plane between the first silicon carbide region and the second silicon carbide regions is located at a distance of 10 mm from the first main surface toward the second main surface,
a value—obtained by dividing the number of void defects in the first silicon carbide region by a sum of the number of the void defects in the first silicon carbide region and the number of void defects in the second silicon carbide region is 0.8 or more, and
in a cross section parallel to the first main surface, the void defects each have a major axis of 1 μm to 1000 μm.

2. The silicon carbide single crystal according to claim 1, wherein in a direction perpendicular to the first main surface, the silicon carbide single crystal has a thickness of 30 mm or more.

3. The silicon carbide single crystal according to claim 1, wherein in a cross section parallel to the first main surface, an area density of the void defects in the first silicon carbide region is 0.1/cm² or more.

4. A method of manufacturing a silicon carbide single crystal, the method comprising:
disposing a silicon carbide seed substrate and a silicon carbide source material in a crucible,
the silicon carbide seed substrate having a growth surface facing the silicon carbide source material and an attachment surface opposite to the growth surface;
forming a first silicon carbide region on the growth surface by sublimating the silicon carbide source material while maintaining a temperature of the growth surface at 2100° C. or higher and lower than 2200° C.; and
forming a second silicon carbide region on the first silicon carbide region by sublimating the silicon carbide source material while maintaining the temperature of the growth surface at 2200° C. or higher, a pressure in the crucible at 0.5 kPa or less, and a temperature gradient between the growth surface and a surface of the silicon carbide source material at 0.4° C./mm or less,
wherein the first silicon carbide region and the second silicon carbide region each include a silicon carbide single crystal of 4H polytype.

5. The method of manufacturing a silicon carbide single crystal according to claim 4, wherein the first silicon carbide region has a thickness of 10 mm or less.

6. The method of manufacturing a silicon carbide single crystal according to claim 4, wherein the silicon carbide single crystal has a thickness of 30 mm or more.

7. The silicon carbide single crystal according to claim 2, wherein in a cross section parallel to the first main surface, an area density of the void defects in the first silicon carbide region is 0.1/cm² or more.

8. The method of manufacturing a silicon carbide single crystal according to claim 5, wherein the silicon carbide single crystal has a thickness of 30 mm or more.
